(19) United States
(12) Patent Application Publication
(10) Pub. No.: US 2021/0272619 A1
(43) Pub. Date: Sep. 2, 2021

(54) Data Storage With Improved Read Performance By Avoiding Line Discharge

(71) Applicant: Western Digital Technologies, Inc., San Jose, CA (US)

(72) Inventors: Refael BEN-RUBI, Rosh Haayin (IL); Moshe COHEN, Modi'in (IL)

(21) Appl. No.: 16/805,574

(22) Filed: Feb. 28, 2020

(51) Int. Cl. G11C 11/4093; G11C 11/408; G11C 11/4094; G11C 11/4074; G11C 16/26

(52) U.S. Cl. CPC G11C 11/4093; G11C 11/4085; G11C 16/26; G11C 11/4074; G11C 11/4094

(57) ABSTRACT

The present disclosure generally relates to efficient reading that avoids line discharging between reads. When multiple read commands are present for a common word line, those read commands can be arranged from lowest sensing voltage to highest sensing voltage. Because the sensing voltage increases for each read command, and the read commands are for the same word line, the normal discharge that occurs after the sensing in the read operation can be eliminated until the highest sensing voltage read command has been executed. At that point, the discharging can occur. Because a discharge does not occur after each sensing in the read operation, the read efficiency is improved.

### BACKGROUND OF THE DISCLOSURE

### Field of the Disclosure

Embodiments of the present disclosure generally relate to efficient reading that avoids line discharging between reads.

### Description of the Related Art

In non-volatile memory, such as NAND flash memory, write and read operations are executed in order to write and read data to/from the memory device. A read operation comprises sense and transfer sub operations. The sense operation of one of several sub operations.

During a read operation, voltages are applied to the word line and bit line to sense the voltage for the location where the data is located. Charge can buildup on the word lines, as well as the bit lines, during the read operation. Therefore, it is common to discharge the word line and bit line once the data has been read. The discharge occurs between reads. In other words, each read operation involves at least one discharge before the next read operation occurs.

Discharging the word line and bit line takes time. When there is a die with many blocks, parasitic capacitance increases, and the line charging and discharging time for the sensing sub operation is increased. When the read operation is too slow, some of the read user's scenario is inefficient.

Therefore, there is a need in the art for a read operation that increases read efficiency.

### SUMMARY OF THE DISCLOSURE

The present disclosure generally relates to efficient reading that avoids line discharging between reads. When multiple read commands are present for a common word line, those read commands can be arranged from lowest sensing voltage to highest sensing voltage. Because the sensing voltage increases for each read command, and the read commands are for the same word line, the normal discharge that occurs after the sensing in the read operation can be eliminated until the highest sensing voltage read command has been executed. At that point, the discharging can occur. Because a discharge does not occur after each sensing in the read operation, the read efficiency is improved.

In one embodiment, a data storage device comprises: a memory device; and a controller coupled to the memory device. The controller is configured to: receive a plurality of read commands for a word line; reorder the read commands from lowest sensing voltage to highest sensing voltage; and execute the read commands, wherein executing the read commands includes sensing voltage and wherein the word line is not discharged between read commands.

In another embodiment, a data storage device comprises: a memory device; and a controller coupled to the memory device. The controller is configured to: receive a first read command for a word line, wherein the first read command has a first sense voltage; review read queue for additional read commands for the word line; determine that a second read command is present in the read queue; execute the second read command; execute the first read command, wherein the first read command is executed prior to discharging the word line; and discharge the word line.

In another embodiment, a data storage device comprises: a memory device; means to rearrange an order of execution of a plurality of read commands for a word line; and means to execute the plurality of read commands without discharging the word line between execution of each read command.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a schematic illustration of a system for storing data.

FIG. 2A is a schematic illustration of the 8 voltage levels for read operation for TLC memory.

FIG. 2B is a schematic illustration of voltage versus time for a read sensing operation.

FIG. 3 is a schematic illustration of a memory device page having multiple bit lines and word lines.

FIG. 4 is a flowchart illustrating a read sensing operation according to one embodiment.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

In the following, reference is made to embodiments of the disclosure. However, it should be understood that the disclosure is not limited to specific described embodiments. Instead, any combination of the following features and elements, whether related to different embodiments or not, is contemplated to implement and practice the disclosure. Furthermore, although embodiments of the disclosure may achieve advantages over other possible solutions and/or over the prior art, whether or not a particular advantage is achieved by a given embodiment is not limiting of the disclosure. Thus, the following aspects, features, embodiments and advantages are merely illustrative and are not considered elements or limitations of the appended claims except where explicitly recited in a claim(s). Likewise, reference to “the disclosure” shall not be construed as a generalization of any inventive subject matter disclosed herein and shall not be considered to be an element or limitation of the appended claims except where explicitly recited in a claim(s).

The present disclosure generally relates to efficient reading that avoids line discharging between reads. When multiple read commands are present for a common word line, those read commands can be arranged from lowest sensing voltage to highest sensing voltage. Because the sensing voltage increases for each read command, and the read commands are for the same word line, the normal discharge that occurs after the sensing in the read operation can be eliminated until the highest sensing voltage read command has been executed. At that point, the discharging can occur. Because a discharge does not occur after each sensing in the read operation, the read efficiency is improved.

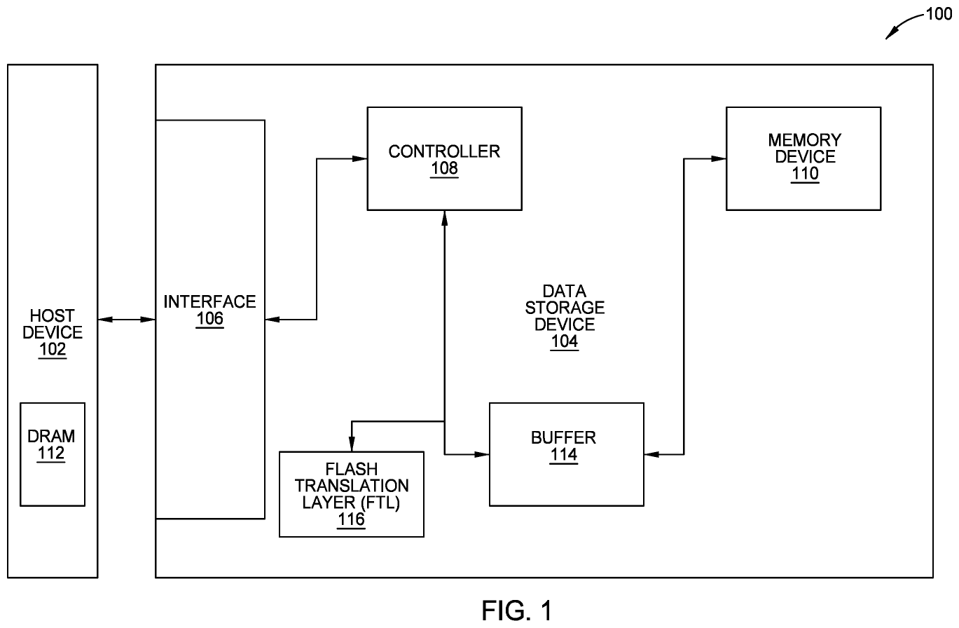

FIG. 1 is a schematic illustration of a system 100 for storing data. The system 100 for storing data according to one embodiment includes a host device 102 and a data storage device 104. The host device 102 includes a dynamic random-access memory (DRAM) 112. The host device 102 may include a wide range of devices, such as computer servers, network attached storage (NAS) units, desktop computers, notebook (i.e., laptop) computers, tablet computers (i.e., “smart” pad), set-top boxes, telephone handsets (i.e., “smart” phones), televisions, cameras, display devices, digital media players, video gaming consoles, video streaming devices, and automotive applications (i.e., mapping, autonomous driving). In certain embodiments, host device 102 includes any device having a processing unit or any form of hardware capable of processing data, including a general purpose processing unit, dedicated hardware (such as an application specific integrated circuit (ASIC)), configurable hardware such as a field programmable gate array (FPGA), or any other form of processing unit configured by software instructions, microcode, or firmware.

The data storage device 104 communicates with the host device 102 through an interface 106 included in the data storage device 104. The data storage device 104 includes a controller 108, a buffer 114, a flash translation layer (FTL) 116, and one or more memory devices 110. The data storage device 104 may be an internal storage drive, such as a notebook hard drive or a desktop hard drive. Data storage device 104 may be a removable mass storage device, such as, but not limited to, a handheld, removable memory device, such as a memory card (e.g., a secure digital (SD) card, a micro secure digital (micro-SD) card, or a multimedia card (MMC)) or a universal serial bus (USB) device. Data storage device 104 may take the form of an embedded mass storage device, such as an eSD/eMMC embedded flash drive, embedded in host device 102. Data storage device 104 may also be any other type of internal storage device, removable storage device, embedded storage device, external storage device, or network storage device.

Memory device 110 may be, but is not limited to, internal or external storage units. The memory device 110 relies on a semiconductor memory chip, in which data can be stored as random-access memory (RAM), read-only memory (ROM), or other forms for RAM and ROM. RAM is utilized for temporary storage of data whereas ROM is utilized for storing data permanently.

Data storage device 104 includes a controller 108 which manages operations of data storage device 104, such as writes to or reads from memory device 110. The controller 108 executes computer-readable program code (e.g., software or firmware) executable commands (herein referred to as “commands”) for the transfer of data. The commands may be executed by various components of controller 108 such as processor, logic gates, switches, applications specific integrated circuits (ASICs), programmable logic controllers embedded microcontrollers, and other components of controller 108.

Data storage device 104 includes a buffer 114 which is a region of physical memory storage used to temporarily store data while it is being moved from one place to another (i.e., from host device 102 to data storage device 104).

In some embodiments, the FTL 116 may perform logical-to-physical address translation, garbage collection, wear-leveling, error correction code (ECC), bad block management, and other functions not listed. The logical-to-physical address translation relates to the mapping of logical addresses from the file system to physical addresses of the memory device 110, such as NAND flash memory.

Data may be transferred to or from the DRAM 112 of the host device 102 to the data storage device 104. One data transfer pathway may originate from the DRAM 112 of the host device 102 and communicate through the interface 106 of the data storage device 104 to the controller 108. The data will then pass through the buffer 114 of the data storage device 104 and be stored in the memory device 110. The controller 108 is configured to update the FTL 116 translation table of the data locations of the within a memory device 110.

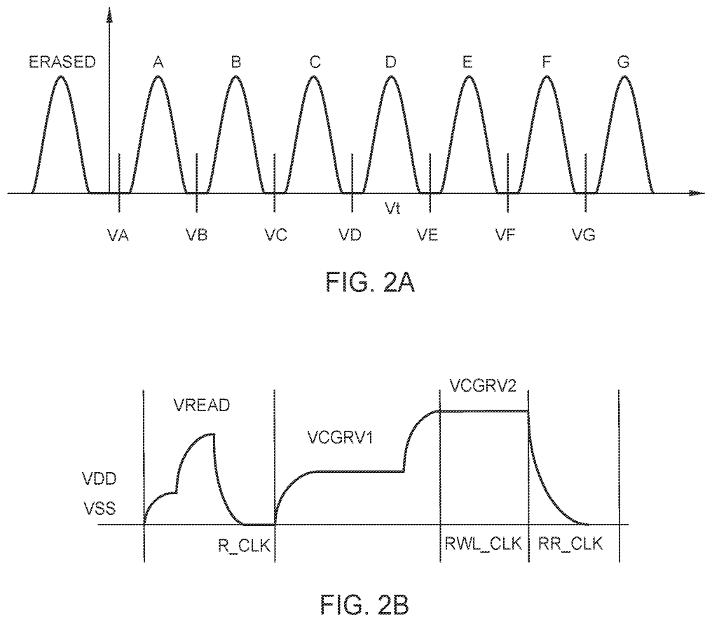

FIG. 2A is a schematic illustration of the 8 voltage levels for read operation for TLC memory. TLC memory is composed of 3 bits in which either a program state of 0 or 1 can exist. The program state refers to the state of the memory cell, whether the memory cell is empty (i.e., no data exists) or the memory cell is programmed (i.e., data exists). Furthermore, the number of unique combinations of program states can be solved in the following equation: (Total number of voltage levels)=2 (number of bits per memory cell). For the TLC memory, the number of voltage levels is eight because 2\hat{ }3=8.

As the number of bits increases, the memory cell can record more information leading to larger data storage. Furthermore, the equation for unique combination of program states may be applied to SLC memory, TLC memory, QLC memory, penta-layer cell (PLC) memory, and other higher iterations of layer cell memory.

The program state of 0 refers to a programmed state whereas the program state of 1 refers to an erased state. The TLC memory has 8 voltage levels, where one is erased and seven are programmed. Furthermore, the one voltage level that is erased has a bit combination of 111. For any memory cell, if the bit combination only contains the program state 1, then the program state is erased (e.g., 1 for SLC, 11 for MLC, and 1111 for QLC). Listing from lowest threshold voltage, denoted by Vt on the x-axis, to highest threshold voltage in FIG. 2, the voltage levels are 111 for the erased cell state, 110 for cell state A, 100 for cell state B, 000 for cell state C, 010 for cell state D, 011 for cell state E, 001 for cell state F, and 101 for cell state G.

The bits for the cell state (i.e., ###) are upper page, middle page, lower page. Furthermore, the lines between the curves are labeled A, B, C, D, E, F, and G are related to the threshold or reference voltage. For other memory cells, the number of threshold or reference voltages can be solved by the following equation: (number of threshold or reference voltages)=(total number of voltage levels)−1. The individual pages of data can be read by performing a number of comparisons at threshold points, determining whether the cell voltage is lower or higher than the threshold. The number of comparisons required for each page read depends upon the bit encoding employed. In FIG. 2, the programmed states are represented by the probability-distribution ‘bumps’ at the top and the threshold voltage positions listed at the bottom (i.e., A-G with the vertical lines). Various encoding schemes are possible, but currently, a 2-3-2 scheme is used as shown in the Table.

TABLE

| Cell State | Erase | A | B | C | D | E | F | G |
|---|---|---|---|---|---|---|---|---|
| Upper page read | 1 | 1 | 1 | 0 | 0 | 0 | 0 | 1 |
| Middle page read | 1 | 1 | 0 | 0 | 1 | 1 | 0 | 0 |
| Lower page read | 1 | 0 | 0 | 0 | 0 | 1 | 1 | 1 |

FIG. 2B is a schematic illustration of voltage versus time for a read sensing operation. When the storage device, such as the data storage device 104 of FIG. 1, receives a read command for a logical block address (LBA), the controller, such as the controller 108 of FIG. 1, determines the location of the LBA within a translation table. The location of the LBA is denoted by the intersection of the word line and the bit line. In order to determine whether the node (i.e., intersection of the word line and the bit line) contains data, a read sense operation may be utilized.

During a read sense operation, voltage is delivered to the word line (WL) that the LBA is on to boost the voltage from VSS (i.e., zero voltage) to VDD (i.e., supply voltage). During the VREAD stage, the voltage spikes in order to clean up the channel prior to sensing. The voltage spike is due to the need to discharge any stored electrons due to imperfections in the production metal. The VREAD spike voltage is discharged to VSS to prepare for the sense operation.

After the initial VREAD spike voltage is discharged, the bit line is charged to VCGRV1. Subsequently, the word line is charged to VCGRV2. At a voltage of VCGRV1 and VCGRV2, the sense amplifier (SA) determines the state of the bit (i.e., 1 or 0). The state of the bit may be registered by the process of comparison of the voltage to the thresholds outlined above in regards to FIG. 2A. The boost from VSS to VDD, VREAD spike, and the VCGRV1 read sense operation is the initial clock phase, R_CLK. The read sense operation at VCGRV2 is the second clock phase, RWL_CLK, of the read operation. Note that there is no discharge between charging the bit line to VCGRV1 and charging the word line to VCGRV2.

After the two threshold voltages are determined, the voltage is discharged from the word lines and the internal high voltage nodes. However, when the voltage is discharged, some of the voltage may be retained in the production metal due to its natural capacitance. The discharge is the final stage of the clock phase, denoted as RR_CLK.

In addition, the process listed may occur in the same order that the read sense operations for the same word line are received in. However, if the read sense operations are re-ordered, so that the voltages needed for a read sense operation are in order from low to high, the overall operation may be optimized or improved. For example, if the following three senses are received in order: high read sense voltage, medium read sense voltage, and low read sense voltage. Each time a sense operation occurs, the word line and internal high voltage nodes are required to be discharged before the subsequent sense operation occurs due to the retention of voltage in the production metal. Furthermore, the VREAD spike will need to occur to flush the channel of any retained electrons prior to the bit line and word line charge of each read sense.

However, if the order of the read sense operations for the same word line is rearranged from low read sense voltage to medium read sense voltage to high read sense voltage, the need for a voltage discharge and a VREAD spike to clear the channel may be eliminated. The VREAD spike occurs prior to the low read sense voltage. The word line and bit line is charged from low read sense voltage to medium read sense voltage and from medium read sense voltage to high read sense voltage. After the high read sense voltage occurs, the discharge of voltage from the word line and the high voltage nodes occurs. Thus, if the read sense operations are reordered from low voltage to high voltage required, read time may be decreased by not having as many discharge operations as well as the voltage required for the overall operation may be less.

Thus, when a read access arrives for execution, the firmware will look to see if there are any pending read requests for the same word line. If the firmware encounters any other read operations from pages in the same word line, the firmware will change the order of the reads to be optimal from a sensing point of view. The criteria for choosing the page read order is the next sense will be to pages for which the needed word line charge addition is minimum. In this manner, there will be no need to discharge and charge again. In the best case scenario for QLC memory with 16 voltage levels, 16 senses can occur without any discharge between senses. However, so long as there are two senses for a single word line that can be rearranged, efficiencies are gained. For different pages, the firmware will take one level sense that belongs to one page sense and execute the one page sense before or after a second level sense that belongs to a second page sense. The firmware will execute the different page senses in an order that is optimal.

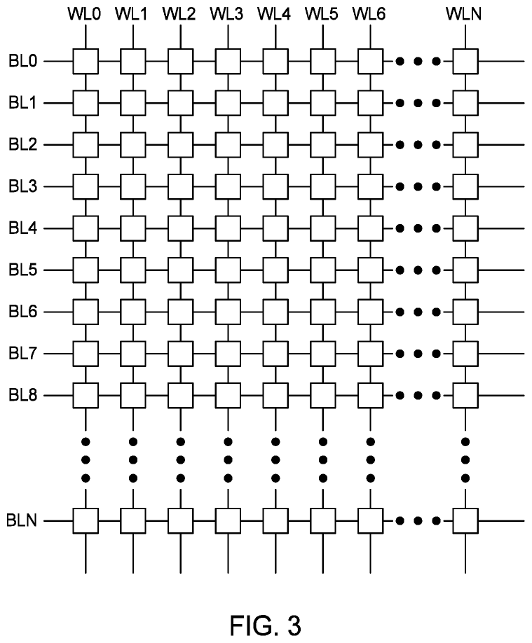

FIG. 3 is a schematic illustration of a memory device page having multiple bit lines and word lines. Each node of the page is where a word line and bit line intersect (e.g., WL0 and BL0 intersect at the top left node 1 of the page). The node represents a possible location for a data to be stored within a memory cell. The word lines are denoted by the horizontal lines and the bit lines are denoted by the vertical lines.

Furthermore, FIG. 3 may describe a page within a memory device, such as the memory device 110 of FIG. 1. The memory device, such as NAND flash memory, may comprise one or more dies. Each of the one or more dies comprises one or more planes. Each of the one or more planes comprises one or more erase blocks. Each of the one or more erase blocks comprises one or more word lines (e.g., 256 word lines). Each of the one or more word lines may be addressed in one or more pages. A page size may be 16K×8 bits or 128 kB. The page size is not limiting nor restricting and other sizes for pages may be applicable. Data is generally written sequentially to the word lines on a page (i.e., in the order of WL0 to WL1 to WL2 and so forth). 272247

The node may consist of a floating gate transistor that has a control gate, floating gate, insulator, P-substrate, source, and a drain. The word lines plug into the transistor's control gate, and the bit lines link the source and the drain to the cell. Electrical current enters the cell through the source and exits through the drain. When a voltage is applied to the word line, the control gate opens and determines if the cell holds a charge (i.e., the bit is a 0 or a 1). A bit state of 1 refers to an erased cell where there are no electrons present in the floating gate. However, if there are electrons in the floating gate, the bit state of the cell is a 0, referring to a cell that contains data. When a positive charge is applied to the bit line and the word line, electrons in the source are moved to the drain. When the electrons are traveling from source to train, some electrons may bypass the insulator and enter the floating gate, thus writing data to the cell.

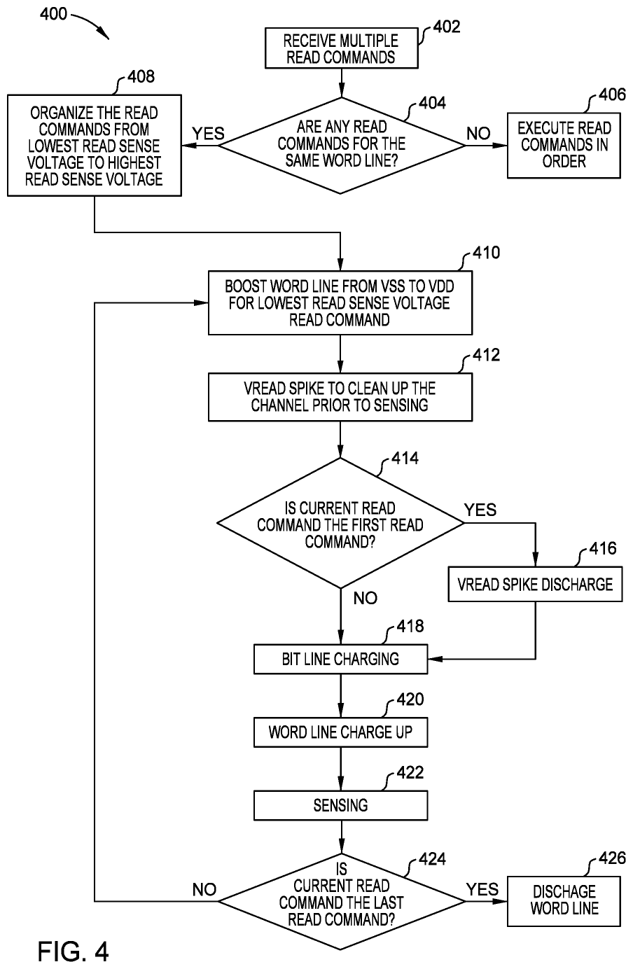

FIG. 4 is a flowchart 400 illustrating a read sensing operation according to one embodiment. The method illustrates possible embodiments of FIG. 2A, FIG. 2B, and FIG. 3. The method is used to determine an efficient process to read data from an individual word line.

At block 402, the storage device, such as the storage device 104 of FIG. 1, receives multiple read commands. The controller, such as controller 108, determines if any of the read commands are for the same word line at block 404. If the read commands are not for the same word line, then at block 406, the read commands are executed in order.

However, if the read commands are for the same word line, then the controller organizes the read commands from lowest read sense voltage to highest read sense voltage at block 408. For example, for three read commands received in random order where the first read command is a high read sense voltage, the second read command is a medium read sense voltage, and the third read command is a low read sense voltage, the controller will reorder the read commands in the order of third read command (i.e., low read sense voltage), second read command (i.e., medium read sense voltage), and first read command (i.e., high read sense voltage).

A voltage is applied to the word line to boost the charge from VSS to VDD for the lowest read sense voltage read command at block 410. VSS may be considered as the ground voltage or zero voltage. VDD may be considered as the source voltage or the voltage that is applied to the word line. At block 412, the voltage increases, denoted by VREAD spike, to clean up the channel prior to sensing.

Following the VREAD spike, the controller determines if the current read command is the first read command at block 414. If the current read command is the first read command, the VREAD spike is discharged to clear the channel of any residual electrons at block 416 and then proceeds with bit line charging at block 418. If the current read command is not the first read command or if the VREAD spike has been discharged, the bit line is charged at block 418, which may be VCGRV1 of FIG. 2B. Following the bit line charge at block 418, the word line is charged at block 420, which may be VCGRV2 of FIG. 2B.

The controller determines the bit state of the memory cell utilizing the sense amplifier at block 422. The bit state of the memory cell is determined by the VCGRV1 from the bit line charge and the VCGRV2 from the word line charge. VCGRV1 may be the lower voltage threshold and VCGRV2 may be the upper voltage threshold. The bit state is determined by using a comparison of the voltage to the threshold voltages described in FIG. 2A. After the sense occurs, the controller determines if the current read command is the last read command at block 424. If the current read command is not the last read command (i.e., additional read commands are in the queue), then the process restarts by boosting the word line from VSS to VDD for the subsequent read sense voltage read command at block 410. However, if the current read command is the last read command, then the word line is discharged at block 426.

Consider the following example for FIG. 4. The data storage device receives multiple read commands at block 402, and the multiple read commands are determined to be for the same word line in block 404. The read commands arrived in the following order: high sense read command, medium sense read command, and low sense read command. The controller then organizes the read commands as follows in block 408: low sense read command, medium sense read command, and high sense read command. The controller then proceeds with processing the low sense read command first.

The word line is boosted from VSS to VDD for the low sense read command at block 410. Thereafter, VREAD spike occurs to clean up the channel prior to sensing at block 412. The controller determines that the low sense read command is the first read command at block 414 and thus discharges the VREAD spike at block 416. The bit line is then charged at block 418 followed by charging the word line at block 420. The sensing then occurs at block 422. The controller then determines that the low sense read command is not the last read command at block 424 and therefore prepares to process the next read command (i.e., the medium sense read command).

The word line is then boosted from VSS to VDD for the medium sense read voltage in block 410. VSS at this point in time if the sensing voltage from the previous read command. VREAD spike occurs to clean up the channel prior to sensing in block 412. The controller then determines that the medium sense read command is not the first read command at block 414 and therefore charges the bit line at block 418. The word line is then charged at block 420 followed by sensing the medium sense read command at block 422. The controller then determines that the medium sense read command is not the last read command at block 424 and therefore prepares to process the next read command (i.e., the high sense read command).

The word line is then boosted from VSS to VDD for the medium sense read voltage in block 410. VSS at this point in time if the sensing voltage from the previous read command. VREAD spike occurs to clean up the channel prior to sensing in block 412. The controller then determines that the high sense read command is not the first read command at block 414 and therefore charges the bit line at block 418. The word line is then charged at block 420 followed by sensing the high sense read command at block 422. The controller then determines that the high sense read command is the last read command at block 424 and therefore discharges the word line at block 426.

In one embodiment, a data storage device comprises: a memory device; and a controller coupled to the memory device. The controller is configured to: receive a plurality of read commands for a word line; reorder the read commands from lowest sensing voltage to highest sensing voltage; and execute the read commands, wherein executing the read commands includes sensing voltage and wherein the word line is not discharged between read commands. The controller is further configured to execute a first read command of the plurality of read commands by a process comprising: boosting the word line from VSS to VDD; VREAD spike to clean up a channel prior to sensing; VREAD spike discharge; bit line charging; word line charging; and sensing. The controller is further configured to execute a second read command of the plurality of read commands by a process comprising: boosting the word line from VSS to VDD; VREAD spike to clean up a channel prior to sensing; bit line charging; word line charging; and sensing. The controller is further configured to execute a third read command of the plurality of read commands by a process comprising: boosting the word line from VSS to VDD; VREAD spike to clean up a channel prior to sensing; bit line charging; word line charging; sensing; and discharging the word line. The controller is configured to execute the first read command prior to the second read command, wherein the controller is configured to execute the second read command prior to the third read command. The controller is configured to receive at least one of the second read command and the third read command prior to receiving the first read command. The controller is configured to discharge the word line after a last read command for the word line has been executed.

In another embodiment, a data storage device comprises: a memory device; and a controller coupled to the memory device. The controller is configured to: receive a first read command for a word line, wherein the first read command has a first sense voltage; review read queue for additional read commands for the word line; determine that a second read command is present in the read queue; execute the second read command; execute the first read command, wherein the first read command is executed prior to discharging the word line; and discharge the word line. The second read command for the word line has a second sense voltage that is lower than the first sense voltage. During execution of the second read command a VREAD spike discharge occurs. During execution of the first read command a VREAD spike discharge does not occur. The controller is further configured to determine that a third read command is present in the read queue, wherein the second read command is queued in order prior to the third read command. The controller is further configured to execute the third read command after the first read command and wherein the third read command is executed prior to discharging the word line. During execution of the second read command a VREAD spike discharge occur, wherein during execution of the first read command a VREAD spike discharge does not occur, and wherein during execution of the third read command a VREAD spike discharge does not occur.

In another embodiment, a data storage device comprises: a memory device; means to rearrange an order of execution of a plurality of read commands for a word line; and means to execute the plurality of read commands without discharging the word line between execution of each read command. The data storage device further comprises means to determine that a plurality of read commands for the word line are in a queue. The data storage device further comprises means to execute at least one read command of the plurality of read commands without performing a VREAD spike discharge. The data storage device further comprises means to discharge the word line after executing the plurality of read commands. The data storage device further comprises means to determine that all read commands for the word line have been executed. The data storage device further comprises means to execute a plurality of read commands in queue order where the plurality of read commands are for different word lines.

By ordering read senses along a common word line such that each successive read utilizes an higher sensing voltage, discharging between read sensing can be avoided, which increases read performance and decreases power consumption.

While the foregoing is directed to embodiments of the present disclosure, other and further embodiments of the disclosure may be devised without departing from the basic scope thereof, and the scope thereof is determined by the claims that follow.

1. A data storage device, comprising:
a memory device; and
a controller coupled to the memory device, the controller configured to:
receive a plurality of read commands for a word line;
reorder the read commands from a lowest sensing voltage to a highest sensing voltage; and
execute the read commands, wherein executing the read commands includes ordering the read commands by a sensing voltage for each of the read commands, and wherein the word line is not discharged to a voltage lower than a previous sensing voltage between the read commands.

2. The data storage device of claim 1, wherein the controller is further configured to execute a first read command of the plurality of read commands by a process comprising:
boosting the word line from a first VSS to a first VDD;
increasing a first voltage of a first channel to VREAD spike to clean up the first channel prior to sensing;
discharging the first voltage of the first channel from the VREAD spike;
bit line charging;
word line charging; and
sensing the word line at a first sensing voltage.

3. The data storage device of claim 2, wherein the controller is further configured to execute a second read command of the plurality of read commands by a process comprising:
boosting the word line from a second VSS to a second VDD, wherein the second VSS corresponds to the first sensing voltage;
increasing a second voltage of a second channel to VREAD spike to clean up the second channel prior to sensing;
bit line charging;
word line charging; and
sensing the word line at a second sensing voltage.

4. The data storage device of claim 3, wherein the controller is further configured to execute a third read command of the plurality of read commands by a process comprising:
boosting the word line from a third VSS to a third VDD, wherein the third VSS corresponds to the second sensing voltage;
increasing a voltage of a third channel to VREAD spike to clean up the third channel prior to sensing;
bit line charging;
word line charging;
sensing the word line at a third sensing voltage; and
discharging the word line.

5. The data storage device of claim 4, wherein the controller is configured to execute the first read command prior to the second read command, wherein the controller is configured to execute the second read command prior to the third read command.

6. The data storage device of claim 5, wherein the controller is configured to receive at least one of the second read command and the third read command prior to receiving the first read command.

7. The data storage device of claim 1, wherein the controller is configured to discharge the word line after a last read command for the word line has been executed.

8. A data storage device, comprising:
a memory device; and
a controller coupled to the memory device, the controller configured to:
receive a first read command for a word line, wherein the first read command has a first sense voltage;
review a read queue for additional read commands for the word line;
determine that a second read command is present in the read queue;
execute the second read command;
execute the first read command, wherein the first read command is executed after the execution of the second read command, wherein the first read command is executed prior to discharging the word line, and wherein discharging the word line does not include a VREAD spike discharge; and
discharge the word line.

9. The data storage device of claim 8, wherein the second read command for the word line has a second sense voltage that is lower than the first sense voltage.

10. The data storage device of claim 8, wherein during execution of the second read command a VREAD spike discharge occurs at a second channel.

11. The data storage device of claim 10, wherein during execution of the first read command a VREAD spike discharge does not occur at a first channel.

12. The data storage device of claim 8, wherein the controller is further configured to determine that a third read command is present in the read queue, wherein the second read command is queued in order prior to the third read command.

13. The data storage device of claim 12, wherein the controller is further configured to execute the third read command after the first read command and wherein the third read command is executed prior to discharging the word line.

14. The data storage device of claim 13, wherein during execution of the second read command a VREAD spike discharge occurs at a second channel, wherein during execution of the first read command a VREAD spike discharge does not occur at a first channel, and wherein during execution of the third read command a VREAD spike discharge does not occur at a third channel.

15. A data storage device, comprising:
a memory device;
a means to rearrange an order of execution of a plurality of read commands for a word line, wherein the order of execution is based on a sense voltage of each read command of the plurality of read commands; and
a means to execute the plurality of read commands without discharging the word line between execution of each read command.

16. The data storage device of claim 15, further comprising a means to determine that the plurality of read commands for the word line are in a queue.

17. The data storage device of claim 15, further comprising a means to execute at least one read command of the plurality of read commands without performing a VREAD spike discharge at one or more channels of the word line.

18. The data storage device of claim 15, further comprising a means to discharge the word line after executing the plurality of read commands.

19. The data storage device of claim 15, further comprising a means to determine that all read commands for the word line have been executed.

20. The data storage device of claim 15, further comprising a means to execute a plurality of read commands in a queue order where the plurality of read commands are for different word lines.
